(19) United States
(12) Patent Application Publication
(10) Pub. No.: US 2004/0192064 A1
(43) Pub. Date: Sep. 30, 2004

(54) Method and apparatus for homogeneous mixing

(75) Inventors: Ruei-Hung Jang, Shinjuang City (TW); Tien-Hsing Woo, Taipei (TW); Chih-Lin Ying, Yunghe City (TW); Tsung-Chi Hsieh, Taipei (TW); Shih-Shiung Chen, Hsin-Chu City (TW); Shenq-Yang Shy, Jung Li City (TW)

Correspondence Address: TUNG & ASSOCIATES, 838 W. Long Lake Road, Suite 120, Bloomfield Hills, MI, 48302, US

(73) Assignee: Taiwan Semiconductor Manufacturing Co., Ltd.

(21) Appl. No.: 10/402,680

(22) Filed: Mar. 28, 2003

(51) Int. Cl. H01L 21/302; H01L 21/461

(52) U.S. Cl. 438/745

(57) ABSTRACT

A method and apparatus for mixing a fluid to form a homogeneous mixing volume providing at least two aspiration members at partially immersed in a solution, each of the two aspiration members include an aspiration surface having a plurality of aspiration openings for injecting a pressurized gas flow into the solution to produce a plurality of flow vortices. The aspiration surfaces disposed in opposing gas flow relationship and spaced apart to define an aspiration treatment volume to produce intersecting flow vortices within the aspiration treatment volume; providing a pressurized gas flow to a first aspiration member to produce a first plurality of flow vortices; and, adjusting the pressurized gas flow to a second aspiration member to produce a second plurality of flow vortices to form a homogeneous mixing volume within a portion of the solution.

### FIELD OF THE INVENTION

This invention generally relates to homogenous mixing of fluids and more particularly to a method and apparatus for achieving a homogeneously mixed solution bath, particularly useful in wet etching processes in semiconductor wafer manufacturing processes.

### BACKGROUND OF THE INVENTION

In the field of semiconductor wafer processing it is common practice to subject the semiconductor wafer to immersion in a solution bath for purposes of, for example, cleaning the wafer process surface or conducting an etching process for removing a selected portion of material from the wafer process surface. The cleaning process or etching process is frequently quite sensitive to slight variations in concentration or solubility of the solution. Various types of mixing processes have been in use in other fields, such as mechanically driven mixers where a mechanical source of energy is imparted to stirring members immersed in the solution. In addition, mixers relying on the passing a flow of pressurized gases into a solution where the buoyancy of the gaseous bubbles created are relied on for mixing the solution. Yet other methods rely on the re-circulation of the solution through a solution container where flowing turbulences are created to impart mixing.

Traditional methods of mixing have been found to be inadequate in the semiconductor manufacturing process. Prior art methods of mixing typically rely on the creation of turbulent volume portions within the fluid to achieve mixing of miscible fluids to achieve a homogeneous or mixed solution. The homogeneity of mixing is generally limited by the volumetric size of turbulence disturbances, for example eddy currents, created in the solution by the mixing means. For example, the larger the volumetric size of the turbulent disturbances, the lower the level of homogeneity in the solution. For example, local concentration gradients in a solution are created within the turbulent disturbance volumes where, for example, in a wet etching process localized volume portions of the solution include concentration gradients which upon contacting an immersed substrate result in localized transient non-uniformities in etching rates over the substrate surface. In the semiconductor wafer processing art where features are on the order of 0.25 microns and less, such localized non-uniformities in etching rates are undesirable.

For example, in a gate oxide formation process, for example following shallow trench isolation formation, a silicon nitride layer is removed according to a hot phosphoric acid wet etching process. The uniformity of the etching process is in many cases critical to subsequent processes to form a reliably functioning transistor overlying the silicon semiconductor wafer. Since hot phosphoric acid is selective to silicon nitride etching, an underlying thin silicon oxide layer acts to protect the silicon substrate from contamination. During the wet etching process, as the silicon nitride etching proceeds, solvated silicon and silicon dioxide form as a chemical reaction byproduct of silicon nitride etching, which in the case of inadequate mixing, forms localized volumetric portions adjacent the wafer surface where the solubility limit of silicon dioxide is reached. Undesirably, when the solubility limit of silicon dioxide is reached, silicon dioxide frequently precipitates by nucleation onto the wafer surface where it may readily subsequently grow into larger particles. As a result, the reliability of semiconductor devices is severely compromised, frequently resulting in the rejection of semiconductor wafers and adversely affecting wafer yield.

Thus, there is a need in the semiconductor manufacturing art for a reliable method and apparatus to achieve an acceptable level of mixing homogeneity in wafer processing solutions.

It is therefore an object of the invention to provide a reliable method and apparatus to achieve an acceptable level of mixing homogeneity in wafer processing solutions while overcoming other shortcomings and deficiencies of the prior art.

### SUMMARY OF THE INVENTION

To achieve the foregoing and other objects, and in accordance with the purposes of the present invention, as embodied and broadly described herein, the present invention provides a method and apparatus for mixing a fluid to form a homogeneous mixing volume.

In a first embodiment, the method includes providing at least two aspiration members at least partially immersed in a solution each of the at least two aspiration members including an aspiration surface having a plurality of aspiration openings for injecting a pressurized gas flow into the solution to produce a plurality of flow vortices the aspiration surfaces disposed in opposing gas flow relationship and spaced apart to define an aspiration treatment volume to produce intersecting flow vortices within the aspiration treatment volume; providing a pressurized gas flow to at least a first aspiration member to produce a first plurality of flow vortices; and, adjusting the pressurized gas flow to at least a second aspiration member to produce a second plurality of flow vortices to form a homogeneous mixing volume within a portion of the solution comprising intersection flow vortices.

These and other embodiments, aspects and features of the invention will be better understood from a detailed description of the preferred embodiments of the invention which are further described below in conjunction with the accompanying Figures.

### BRIEF DESCRIPTION OF THE DRAWINGS

FIGS. 1A and 1B are schematic representations of the mixing system according to embodiments the present invention.

FIGS. 2A and 2B are schematic representations of fluid flow velocity vectors in operation according to embodiments the present invention.

FIGS. 3A and 3B are views of embodiments of the aspiration members according to embodiments the present invention.

FIG. 4 is a schematic representations of the mixing system used for performing a semiconductor wafer process according to an embodiment of the present invention,

### DETAILED DESCRIPTION OF THE PREFERRED EMBODIMENTS

Although the method of the present invention in exemplary implementation of the mixing apparatus of the present invention is explained with respect to, and is particularly advantageously used in the semiconductor processing art including wet etching processes, it will be appreciated that the method and apparatus of the present invention may be used in any process where a homogeneous mixing zone may be created within a fluid for advantageously affecting a process, including selectively varying the homogeneous mixing zone over a substrate surface.

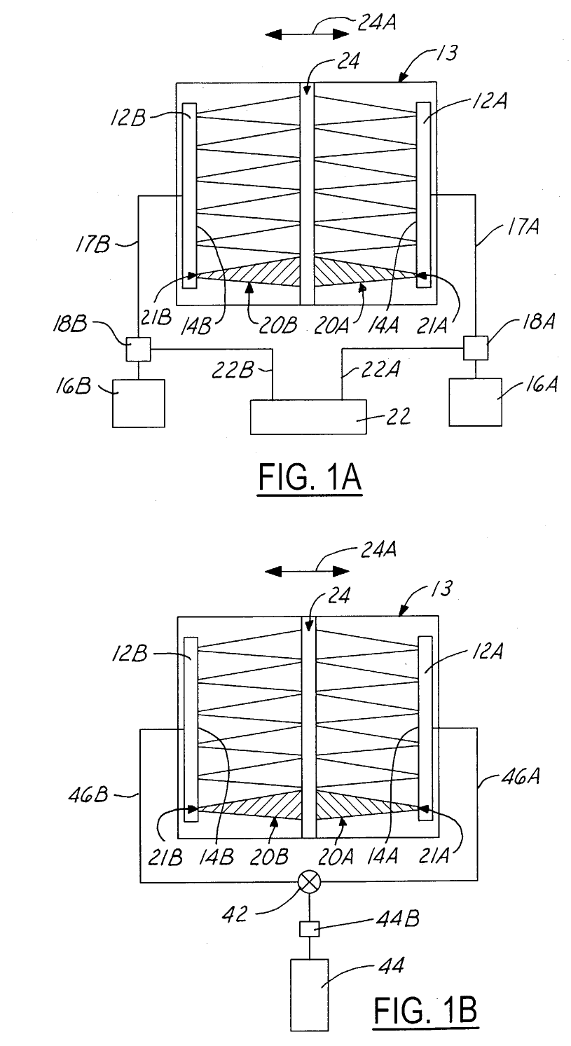

Referring to FIG. 1A, is shown an exemplary embodiment of a configuration of the apparatus of the present invention, the embodiment referred to as a dynamic stagnation zone mixing system for creating a 3-dimensional mixing zone (stagnation zone) in a solution having improved mixing homogeneity. For example, shown FIG. 1A are two aspirating members 12A and 12B immersed in a chemical treatment solution bath 13 and spatially positioned in opposing aspirating relationship, for example adjusting in opposing planar juxtaposition, the aspiration surfaces of the respective aspirating members, 14A and 14B, spatially adjusted to be about parallel to one another and spaced apart a predetermined distance. It will be appreciated that the opposing members may optionally be adjusted out of parallel with respect to one another to vary the geometry of the 3-dimensional mixing zone created within the interposed fluid, for example a chemical treatment solution. The aspiration surfaces of the opposing members, 14A and 14B, including at least one, and preferably a plurality of aspiration openings for the passage of pressurized fluid, for example a gas, through the openings into a second fluid interposed between the opposing aspiration surfaces 14A and 14B. It will be appreciated that the aspirating members 12A and 12B may be include members of any shape as long as they include opposing aspiration surfaces having aspirating openings the aspiration surfaces preferably spatially adjustable with respect to one another to form an opposing aspirating relationship, for example, the aspirating flows of the respective aspirating members positioned substantially opposite to one another. For example, the aspirating members 12A and 12B may be formed in a rectangular or circular shape, but preferably having a major surface forming an aspiration surface, the respective aspiration surfaces of the aspirating members positioned in opposing aspirating relationship. The aspirating members 12A and 12B preferably are separately spatially adjustable members or may be interconnected members for spatial adjustment prior to or subsequent to immersion into a solution to achieve a predetermined opposing aspirating relationship. It will be appreciated that the aspirating members 12A and 12B may alternatively be formed in a fixed position, for example as a portion of a fluid containing vessel wall member, including a container having a radius of curvature such as a pipe, where the aspirating openings are formed in predetermined opposing aspirating relationship to one another along selected opposing radial portions of the fluid contacting walls of the pipe.

Still referring to FIG. 1A, one or more sources of pressurized gas e.g., 16A and 16B, preferably a chemically inert gas such as nitrogen, helium or argon, or mixtures thereof is supplied to each of the aspirating members through one or more gas flow pathways e.g., 17A and 17B respectively, for producing a pressurized aspirated flow of gas (jet vortex) through the respective aspirating members 12A and 12B. It will be appreciated that the pressure of the gas supplied may be varied depending on the desired relative velocity and size of the resulting jet flow vortices e.g., 20A, and 20B. In one embodiment, a gas flow control means, e.g., 18A and 18B, for example including conventional automated gas flow restrictors for regulating a pressure drop and flow rate of the gas supplied to the aspirating members 12A and 12B is included in the gas flow pathways 17A an 17B, respectively. Preferably, a controller, 22 is in communication with gas flow control means 18A and 18B e.g., via communication lines 22A and 22B respectively including a gas flow or gas pressure sensing means to determine a pressure or gas flow rate and responsively adjust the same according to preprogrammed controller instructions.

Still referring to FIG. 1A, an array of jet flow vortices e.g., 20A and 20B are produced from the pressurized aspirated gas flow emanating in opposed relationship from an array of aspiration openings e.g., 21A and 21B, respectively. In exemplary operation, the opposing jet flow vortices meet in opposing flow relationship at a position intermediate between aspirating members 12A and 12B, for example, about a midway point, forming a volumetric portion 24 (stagnation zone) having a reduced net velocity, preferably about a zero net velocity when velocity vectors are added in 3 dimensions. For example, in the exemplary implementation, the stagnation zone 24 is approximated by a planar shaped volume having a width and length approximating the corresponding dimensions of the aspiration surfaces. A thickness of the stagnation zone may vary depending on the spatial relationship of the aspiration openings and the velocity of aspiration flow injected into the interposed solution, as well as the density of the fluid components making up the solution. The stagnation zone 24, preferably having a predetermined width, length and thickness is determined according to equations of motion primarily attributable to the respective velocity vectors associated with the respective impacting opposing jet flow vortices, e.g., 20A and 20B. For example, the impacting flows form a volume (stagnation zone) where the velocity vectors in 3-dimensions substantially cancel one another. For example, the velocity vectors in a volume portion of the impacting flow volume are about equal to one another, additively resulting in about a zero net velocity volume, or alternatively stated, form a near zero mean velocity volume. As a result, the volumetric portion having a reduced net velocity forms a stagnation volume where mixing between miscible fluids in the solution is advantageously substantially increased.

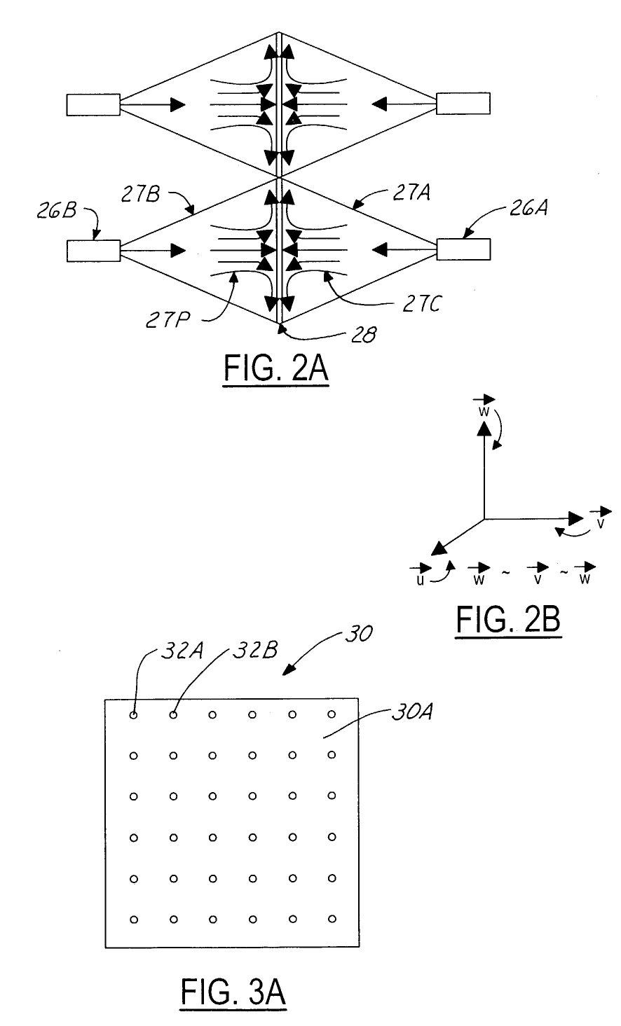

Referring to FIG. 2A, for example is shown a 2-dimensional schematic of the interaction of impacting jet flow vortices formed in opposing aspirating relationship. For example, in cross section, an array of aspiration openings e.g., 26A and 26B are shown in substantially oppositely juxtaposed relationship to one another, each aspiration opening creating a jet flow vortex schematically represented by a cone shaped flow pattern e.g., 27A, 27B. Representative flow vectors included in each jet flow vortex are represented by arrows e.g., 27C and 27D. In operation, the opposing jet flow vortices, e.g., 27A and 27B impact one another defining a reduced net velocity planar shaped volume (stagnation zone) e.g., 28, a major surface of the stagnation zone oriented about perpendicular to the flow direction. Referring to FIG. 2B is shown a representative vector diagram in 3-dimensions showing representative velocity vectors U, V, W having a magnitude and direction respectively corresponding to respective directional axes in X, Y, Z volume space within a portion of the stagnation zone 28. Preferably, within the stagnation zone, the velocity vectors U, V, W are about equal to one another and additively produce about a zero net velocity over an X, Y, Z volume space. It will be appreciated that the ideal result of zero net velocity is approximated in operation, resulting in a substantially reduced net velocity flow and improved homogeneous mixing in the stagnation zone.

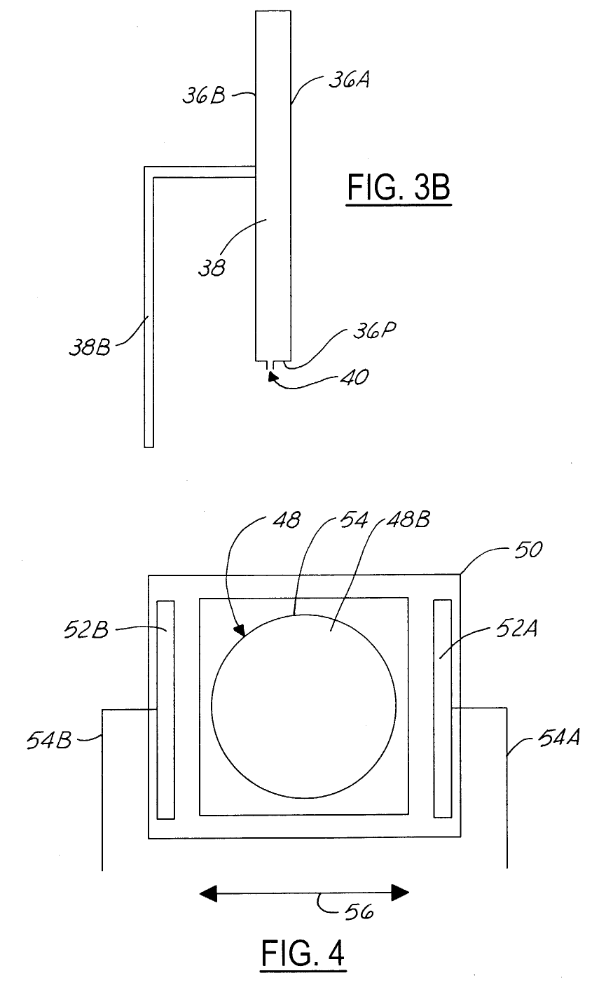

Referring to FIG. 3A, in an exemplary embodiment, is shown a top planar view of an exemplary aspirating member 30, showing a representative arrangement of an array of aspiration openings, e.g., 32A, 32B. Preferably, the array of aspiration openings are formed in a predetermined spatial relationship to form a substantially uniform stagnation zone over the area of impacting opposing aspiration flows. For example, the array of aspiration openings formed in an aspirating surface 30A, is shown having a cubic spaced relationship to one another, where the aspiration openings are spaced about the same distance from one another to form a mesh or array of openings. It will be appreciated that other aspiration opening spacing patterns may be used, the relative spacing determined primarily by spacing between the opposed aspirating members and the size of the jet flow vortices produced in operation. For example, for exemplary use in a semiconductor wafer etching or cleaning operation, the aspirating member may be rectangular shaped an slightly larger than a diameter of the wafers, for example, about 20 cm to about 30 cm on a side depending on the size of the wafers. The aspiration surface 30A preferably includes a plurality of aspiration openings forming a mesh or array where the openings in an exemplary embodiment are spaced apart from one another about 0.5 cm to about 1 cm. The aspiration openings may be formed in conventional venturi shapes, for example, including a cone shaped outlet portion with the cone defining an exit angle of the jet vortex and the cone base flush with the aspirating surface. For example, the aspiration openings may have opening diameters ranging from about 0.1 mm to about 1 mm. The aspiration member 30 is preferably formed of a material resistant to the chemicals used in the cleaning or etching process, for example, quartz, PTFE, and polyethylene. For example, for an etching operation using phosphoric acid, quartz is a suitable chemically resistant material for forming the aspiration members.

Referring to FIG. 3B, a cross sectional side view of an exemplary aspiration member 36 is shown, including a front portion 36A a back portion 36B and side portions 36C and 36D, defining a gas containing space 38 in communication with gas supply pathway 38B. One or more drain outlets e.g., 40 are preferably disposed in a lower portion of the aspiration member, for example side portion 36D, to allow fluid from the treatment solution entering through aspiration openings to drain. For example, it frequently becomes necessary to change the chemical treatment solution within which the aspiration members may be immersed. During the solution change process it is frequently useful to stop the gas flow supplied to the aspiration members. As a result, a portion of the chemical treatment solution enters into the gas containing space 38, which is preferably drained through a drain disposed in a lower portion of the aspiration member to take advantage of the force of gravity.

Referring again to FIG. 1A, in another embodiment the relative gas flow rates or gas pressures supplied to aspiration members 12A and 12B are varied in a predetermined way to modulate the movement of the stagnation zone 24 across the space separating the aspiration members 12A and 12B to form a swept stagnation volume (zone, the direction of movement indicated by directional arrow 24A. As previously explained, the position of the stagnation zone 24, is primarily determined by a net canceling out of velocity vectors of impacting opposing jet vortices. In operation, a relative difference in aspiration flows from the respective aspiration members determines the position of the stagnation zone 24, for example, moving parallel and closer to the aspiration member having a relatively lower aspiration flow rate. Thus, by controllably altering the relative aspirating flow rates the stagnation zone may be selectively swept across the space separating the aspiration members to define a swept stagnation volume. For example, in one embodiment, the relative differences between aspirating gas flow rates emanating from the respective aspiration members are periodically altered to cause the stagnation zone to periodically sweep back and forth between the space separating the respective aspirating members. For example controller, 22 is preprogrammed to selectively alter the relative gas pressures or flow rates supplied to at least one of the respective aspirating members 12A and 12B to cause the stagnation zone to periodically move toward and away from a selected aspiration member to define a swept stagnation volume. For example, the aspirating gas flow rates of the respective aspirating members may be inversely varied with respect to one another periodically, to create a sinusoidally varying relative aspirating gas flow rate difference with respect to time to form a periodically moving stagnation plane defining a swept stagnation volume.

In another embodiment, referring to FIG. 1B, the gas flow to the respective aspiration members is varied periodically in an on/off relationship to approximate a square wave variation of aspirating gas flow in time. For example, the periodically moving stagnation zone is achieved by alternately supplying a predetermined gas flow or pressure to the respective aspiration members. For example, a gas flow control valve 42, for example including a two-way gas flow switching means, is periodically alternatively switched to direct the gas flow supplied from a common gas source e.g., 44, including gas flow control means 44B, to the respective aspiration members, for example along gas flow pathways 46A and 46B. For example, a conventional solenoid valve with a self contained automated timing mechanism may be used to alternately switch a gas flow to the respective aspiration members. It will be appreciated that the aspiration members may be separately supplied with gas sources, the alternated gas flow on and gas flow off states controlled by a gas flow control or pressure control means as previously shown in FIG. 1A. In operation, the stagnation zone moves away from the aspiration member in an gas flow on state toward the aspiration member in a gas flow off state thereby periodically sweeping out a stagnation volume by alternating the respective gas flow states of the aspiration members. It will be appreciated that the swept stagnation volume may be altered by variation of several variables including the period of variation of the relative gas flow rates or gas pressures supplied to the aspiration members, the spacing between aspiration members, and the mesh size of the aspiration openings.

For example referring to FIG. 4, in an exemplary implementation, a side view of a portion of a dynamic stagnation plane mixing system is shown where one or more semiconductor wafers e.g., 48, with process surface 48B, are immersed in a solution container 50 containing a treatment solution (not shown) covering the wafers. Aspiration members, e.g., 52A and 52B including gas supply lines 54A, 54B, are arranged one either side of the wafers e.g., 48 with major faces in opposing parallel aspirating relationship the aspirating surfaces about perpendicular to the wafer edges and producing a aspirating flow about parallel to the wafer process surface 48B. The aspiration members, e.g., 52A and 52B are further sized and arranged such that a stagnation zone preferably extends across the diameter of the wafers including aspirating gas flow rates supplied in a predetermined periodically varying manner to form a swept stagnation volume e.g., shown in 2 dimensions as box 54 defined by periodic movement back and forth as shown by directional arrow 56, of the stagnation zone preferably encompassing the entire wafer process surface.

Thus, a mixing apparatus for aspirated mixing of a chemical treatment solution has been presented for producing a mixing zone having improved homogeneous fluid mixing. The apparatus is particularly useful in semiconductor etching or cleaning processes, for example including use in a hot phosphoric acid etching process for removing silicon nitride. The homogeneous fluid mixing zone reduces concentration gradients in the solution thereby preventing nucleation and growth of chemical species in solution, for example silicon dioxide. The dynamic stagnation zone mixing system and method has the advantages of the ability to homogeneously mix a large volume of fluid at a relatively lower energy cost compared to mechanical mixing means and achieve superior homogeneity compared to prior art aspirated mixing means. The dynamic stagnation zone mixing system has the further benefits of being easily maintained and cleaned to increase a process throughput.

The preferred embodiments, aspects, and features of the invention having been described, it will be apparent to those skilled in the art that numerous variations, modifications, and substitutions may be made without departing from the spirit of the invention as disclosed and further claimed below.

What is claimed is:

1. A fluid mixing apparatus for creating a homogeneous mixing zone in a fluid volume comprising:
at least two aspiration members each comprising an aspiration surface including a plurality of aspiration openings for injecting a first pressurized fluid into a second fluid to produce a plurality of aspirated flows the aspiration surfaces disposed facing one another in opposing flow relationship and spaced apart to define an aspiration treatment volume; and,
at least one first pressurized fluid source communicating with the at least two aspiration members including a means to variably control an aspirated flow rate through the plurality of aspiration openings.

2. The fluid mixing apparatus of claim 1, wherein each of the aspiration surfaces defines a plane.

3. The fluid mixing apparatus of claim 1, wherein each of the aspiration surfaces are positioned to be substantially parallel to one another.

4. The fluid mixing apparatus of claim 1, wherein the aspiration openings are formed in an array having a predetermined spacing such that intersecting opposing aspirated flows produced by the aspiration members forms a substantially homogeneous mixing volume having a reduced flow velocity magnitude and direction.

5. The fluid mixing apparatus of claim 4, wherein the predetermined spacing is from about 0.5 mm to about 5 mm.

6. The fluid mixing apparatus of claim 5, wherein each of the plurality of aspiration openings has a minimum diameter of about 0.1 mm to about 1 mm.

7. The fluid mixing apparatus of claim 6, wherein the at least two aspiration members have rectangular shaped aspiration surfaces having dimensions of from about 20 cm to about 30 cm on a side.

8. The fluid mixing apparatus of claim 1, wherein each of the plurality of aspiration openings forms a venturi.

9. The fluid mixing apparatus of claim 1, wherein the means to variably control an aspiration flow rate comprises a switchable gas flow control valve to including a means to periodically alternate aspiration gas flow to the at least two aspiration members.

10. The fluid mixing apparatus of claim 1, wherein the means to variably control an aspiration flow rate comprises at least one of a mass flow controller and a gas flow restrictor in responsive communication with a pre-programable controller for selectively altering an aspiration flow rate to the at least two aspiration members.

11. A method for mixing a fluid to form a homogeneous mixing volume comprising the steps of:
providing at least two aspiration members at least partially immersed in a solution each of the at least two aspiration members comprising an aspiration surface including a plurality of aspiration openings for injecting a pressurized gas flow into the solution to produce a plurality of flow vortices the aspiration surfaces disposed in opposing gas flow relationship and spaced apart to define an aspiration treatment volume to produce intersecting flow vortices within the aspiration treatment volume;
providing a pressurized gas flow to at least a first aspiration member to produce a first plurality of flow vortices;
adjusting the pressurized gas flow to at least a second aspiration member to produce a second plurality of flow vortices to form a homogeneous mixing volume within a portion of the solution comprising intersection flow vortices.

12. The method of claim 11, wherein the homogeneous mixing volume comprises solution flow velocity vectors about equal in 3-dimensions to produce a volume portion having about a zero net additive velocity.

13. The method of claim 12, wherein at least one substrate treatment surface is disposed within the aspiration treatment volume.

14. The method of claim 13, wherein the homogeneous mixing volume extends over at least a portion of the at least one substrate treatment surface.

15. The method of claim 11, wherein the at least two aspiration members comprise two aspiration members each having aspiration surfaces disposed facing and substantially parallel to one another.

16. The method of claim 15, wherein the at least one substrate treatment surface comprises at least one semiconductor process wafer surface positioned about parallel to the pressurized gas flow direction.

17. The method of claim 11, wherein the step of adjusting comprises periodically increasing a pressurized gas flow provided to at least one of the at least two aspiration members relative to at least one remaining aspiration member to periodically move the homogeneous mixing volume across a portion of the aspiration treatment volume.

18. The method of claim 16, wherein the step of adjusting comprises periodically increasing a pressurized gas flow provided to one of the aspiration members relative to the other aspiration member to periodically sweep the homogeneous mixing volume across the semiconductor wafer process surface.

19. The method of claim 18, wherein the step of adjusting further comprises alternately supplying a pressurized gas flow to one of the two aspiration members.
